(19) United States
(12) Patent Application Publication
(10) Pub. No.: US 2026/0047259 A1
(43) Pub. Date: Feb. 12, 2026

(54) DISPLAY SUBSTRATE, DISPLAY PANEL, AND METHOD OF MANUFACTURING THE DISPLAY SUBSTRATE

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Can Wang, Beijing (CN); Can Zhang, Beijing (CN); Ying Zhou, Beijing (CN); Xiaochuan Chen, Beijing (CN); Minghau Xuan, Beijing (CN)

(21) Appl. No.: 18/995,809

(22) PCT Filed: May 14, 2024
(86) PCT No.: PCT/CN2024/093136

§ 371 Date: Jan. 16, 2025

(30) Foreign Application Priority Data
Jun. 29, 2023 (CN) 202310788063.7

(51) Int. Cl. H10H 29/855; H10H 20/831; H10H 20/84; H10H 29/01; H10H 29/49

(52) U.S. Cl. CPC H10H 29/855; H10H 20/8314; H10H 20/84; H10H 29/011; H10H 29/012; H10H 29/0363; H10H 29/0364; H10H 29/49

(57) ABSTRACT

Provided is a display substrate, including: a base substrate; a plurality of conductive patterns on base substrate; a plurality of light-emitting elements on base substrate, where the plurality of light-emitting elements are arranged in array and spaced apart from each other, and at least one light-emitting element includes a first electrode, a first type semiconductor layer, a light-emitting layer, a second type semiconductor layer, and a second electrode, first electrode is electrically connected to conductive pattern, first type semiconductor layer is located on a side of first electrode, light-emitting layer is located on a side of first type semiconductor layer, second type semiconductor layer is located on a side of light-emitting layer, and second electrode is located on a side of second type semiconductor layer; and a conductive light-shielding portion on base substrate, located in a gap between two adjacent light-emitting elements, and being electrically connected to second electrode.

### CROSS REFERENCE TO RELATED APPLICATION(S)

This application is a Section 371 National Stage Application of International Application No. PCT/CN2024/093136, filed on May 14, 2024, entitled “DISPLAY SUBSTRATE, DISPLAY PANEL, AND METHOD OF MANUFACTURING THE DISPLAY SUBSTRATE”, which claims priority to Chinese Patent Application No. 202310788063.7 filed on Jun. 29, 2023, the content of which is incorporated herein by reference in its entirety.

### TECHNICAL FIELD

The present disclosure relates to a field of display technology, and in particular to a display substrate, a display panel, and a method of manufacturing the display substrate.

### BACKGROUND

Light Emitting Diode (abbreviated as LED) technology has been developed for nearly thirty years, and its application scope is constantly expanding, for example, it may be used in the display field as a backlight source of a display device or as an LED display screen. With the development of technology, the resolution of a LED display product is gradually improved. As the resolution increases, a pixel pitch in the LED display product gradually decreases. How to design the structure of the display panel in the LED display product with a small pixel pitch to reduce or even avoid crosstalk between pixels is one of the topics that display product developers pay attention to.

The above information disclosed in this section is only for understanding of the background of the inventive concept of the present disclosure. Therefore, the above information may include information that does not constitute the related art.

### SUMMARY

In one aspect, there is provided a display substrate, including: a base substrate; a plurality of conductive patterns located on the base substrate; a plurality of light-emitting elements located on the base substrate, where the plurality of light-emitting elements are arranged in an array and spaced apart from each other on the base substrate, and at least one light-emitting element includes a first electrode, a first type semiconductor layer, a light-emitting layer, a second type semiconductor layer, and a second electrode, where the first electrode is electrically connected to the conductive pattern, the first type semiconductor layer is located on a side of the first electrode away from the base substrate, the light-emitting layer is located on a side of the first type semiconductor layer away from the base substrate, the second type semiconductor layer is located on a side of the light-emitting layer away from the base substrate, and the second electrode is located on a side of the second type semiconductor layer away from the base substrate; and a conductive light-shielding portion located on the base substrate, where the light-shielding portion is located in a gap between two adjacent light-emitting elements, and is electrically connected to the second electrode.

According to some exemplary embodiments, the light-emitting layer includes a top surface away from the base substrate, the light-shielding portion includes a top surface away from the base substrate, and the base substrate includes a first surface facing the light-emitting element; and a height of the top surface of the light-shielding portion relative to the first surface is greater than a height of the top surface of the light-emitting layer relative to the first surface.

According to some exemplary embodiments, the second type semiconductor layer includes a top surface away from the base substrate, and the height of the top surface of the light-shielding portion relative to the first surface is greater than a height of the top surface of the second type semiconductor layer relative to the first surface.

According to some exemplary embodiments, the first type semiconductor layer includes a bottom surface close to the base substrate, the light-shielding portion includes a bottom surface close to the base substrate, and a height of the bottom surface of the light-shielding portion relative to the first surface is less than a height of the bottom surface of the first type semiconductor layer relative to the first surface.

According to some exemplary embodiments, the bottom surface of the light-shielding portion is in contact with the first surface.

According to some exemplary embodiments, the first type semiconductor layer includes a bottom surface close to the base substrate, the light-emitting element includes a sidewall connecting the top surface of the second type semiconductor layer and the bottom surface of the first type semiconductor layer, and the sidewall of the light-emitting element is inclined relative to the bottom surface of the first type semiconductor layer.

According to some exemplary embodiments, the light-shielding portion includes a bottom surface close to the base substrate and a sidewall connecting the top surface of the light-shielding portion and the bottom surface of the light-shielding portion, and the sidewall of the light-shielding portion is inclined relative to the bottom surface of the light-shielding portion.

According to some exemplary embodiments, the sidewall of the light-emitting element is inclined at a first angle relative to the bottom surface of the first type semiconductor layer, and the first angle is less than or equal to 65°; and/or the sidewall of the light-shielding portion is inclined at a second angle relative to the bottom surface of the light-shielding portion, and the second angle is less than or equal to 65°.

According to some exemplary embodiments, the display substrate further includes a first insulating layer located between the second type semiconductor layer and a layer where the second electrode is located; and a plurality of openings located in the first insulating layer; and the first insulating layer includes a first portion and a second portion, where the first portion of the first insulating layer covers a part of the top surface of the second type semiconductor layer, the opening exposes another part of the top surface of the second type semiconductor layer, and the second portion of the first insulating layer covers the sidewall of the light-emitting element.

According to some exemplary embodiments, the second electrode includes a first electrode portion, a second electrode portion, and a third electrode portion, where the first electrode portion covers the first portion of the first insulating layer, the second electrode portion covers the second portion of the first insulating layer, and the third electrode portion is located in the opening; and the light-shielding portion is in contact with at least the first electrode portion of the second electrode.

According to some exemplary embodiments, an orthographic projection of the light-shielding portion on the base substrate is spaced apart from an orthographic projection of the second portion of the first insulating layer on the base substrate.

According to some exemplary embodiments, the light-shielding portion includes a first light-shielding sub-portion and a second light-shielding sub-portion, where the first light-shielding sub-portion is in contact with the first electrode portion of the second electrode, and the second light-shielding sub-portion is in contact with the second electrode portion of the second electrode.

According to some exemplary embodiments, an orthographic projection of the second light-shielding sub-portion on the base substrate at least partially overlaps with an orthographic projection of the second electrode portion of the second electrode on the base substrate; and/or, an orthographic projection of the second light-shielding sub-portion on the base substrate at least partially overlaps with the orthographic projection of the second portion of the first insulating layer on the base substrate.

According to some exemplary embodiments, the second electrode includes a top surface away from the base substrate, and the height of the top surface of the light-shielding portion relative to the first surface is greater than a height of the top surface of the second electrode relative to the first surface.

According to some exemplary embodiments, at least one light-emitting element includes a first light-emitting sub-element and a second light-emitting sub-element, the first light-emitting sub-element and the second light-emitting sub-element are stacked in a direction perpendicular to the first surface of the base substrate, and the first surface is a surface of the base substrate facing the light-emitting element; the first light-emitting sub-element includes a first electrode, a first type semiconductor layer, a light-emitting layer, and a second type semiconductor layer, the first electrode is electrically connected to the conductive pattern, the first type semiconductor layer of the first light-emitting sub-element is located on a side of the first electrode away from the base substrate, the light-emitting layer of the first light-emitting sub-element is located on a side of the first type semiconductor layer of the first light-emitting sub-element away from the base substrate, and the second type semiconductor layer of the first light-emitting sub-element is located on a side of the light-emitting layer of the first light-emitting sub-element away from the base substrate; the second light-emitting sub-element includes a first type semiconductor layer, a light-emitting layer, a second type semiconductor layer, and a second electrode, the first type semiconductor layer of the second light-emitting sub-element is located on a side of the second type semiconductor layer of the first light-emitting sub-element away from the base substrate, the light-emitting layer of the second light-emitting sub-element is located on a side of the first type semiconductor layer of the second light-emitting sub-element away from the base substrate, the second type semiconductor layer of the second light-emitting sub-element is located on a side of the light-emitting layer of the second light-emitting sub-element away from the base substrate, and the second electrode is located on a side of the second type semiconductor layer of the second light-emitting sub-element away from the base substrate; and the second type semiconductor layer of the first light-emitting sub-element and the first type semiconductor layer of the second light-emitting sub-element are electrically connected through a first bonding layer.

According to some exemplary embodiments, the light-emitting layer of the second light-emitting sub-element includes a top surface away from the base substrate, the light-shielding portion includes the top surface away from the base substrate, and the height of the top surface of the light-shielding portion relative to the first surface is greater than a height of the top surface of the light-emitting layer of the second light-emitting sub-element relative to the first surface; and/or, the light-emitting layer of the first light-emitting sub-element includes a bottom surface close to the base substrate, the light-shielding portion includes the bottom surface close to the base substrate, and a height of the bottom surface of the light-shielding portion relative to the first surface is less than a height of the bottom surface of the light-emitting layer of the first light-emitting sub-element relative to the first surface.

According to some exemplary embodiments, the second type semiconductor layer of the second light-emitting sub-element includes a top surface away from the base substrate, and the height of the top surface of the light-shielding portion relative to the first surface is greater than a height of the top surface of the second type semiconductor layer of the second light-emitting sub-element relative to the first surface; and/or, the first type semiconductor layer of the first light-emitting sub-element includes a bottom surface close to the base substrate, and the height of the bottom surface of the light-shielding portion relative to the first surface is less than a height of the bottom surface of the first type semiconductor layer of the first light-emitting sub-element relative to the first surface.

According to some exemplary embodiments, the bottom surface of the light-shielding portion is in contact with the first surface.

According to some exemplary embodiments, the light-emitting element includes a sidewall connecting the top surface of the second type semiconductor layer of the second light-emitting sub-element and the bottom surface of the first type semiconductor layer of the first light-emitting sub-element, and the sidewall of the light-emitting element is inclined relative to the bottom surface of the first type semiconductor layer of the first light-emitting sub-element.

According to some exemplary embodiments, the light-shielding portion includes the bottom surface close to the base substrate and a sidewall connecting the top surface of the light-shielding portion and the bottom surface of the light-shielding portion, and the sidewall of the light-shielding portion is inclined relative to the bottom surface of the light-shielding portion.

According to some exemplary embodiments, the sidewall of the light-emitting element is inclined at a first angle relative to the bottom surface of the first type semiconductor layer, and the first angle is less than or equal to 65°; and/or, the sidewall of the light-shielding portion is inclined at a second angle relative to the bottom surface of the light-shielding portion, and the second angle is less than or equal to 65°.

According to some exemplary embodiments, the first bonding layer includes a bottom surface facing the second type semiconductor layer of the first light-emitting sub-element, a top surface facing the first type semiconductor layer of the second light-emitting sub-element, and a sidewall connecting the bottom surface of the first bonding layer and the top surface of the first bonding layer; and the sidewall of the first bonding layer is inwardly recessed relative to the sidewall of the second type semiconductor layer of the adjacent first light-emitting sub-element, and/or the sidewall of the first bonding layer is inwardly recessed relative to the sidewall of the first type semiconductor layer of the adjacent second light-emitting sub-element.

According to some exemplary embodiments, the display substrate further includes a lens located on the base substrate, the lens is located on a side of the second electrode away from the base substrate, and an orthographic projection of the lens on the base substrate covers an orthographic projection of the opening on the base substrate.

According to some exemplary embodiments, the orthographic projection of the lens on the base substrate at least partially overlaps with an orthographic projection of the second portion of the first insulating layer on the base substrate; and/or, the orthographic projection of the lens on the base substrate at least partially overlaps with an orthographic projection of the second portion of the second electrode on the base substrate.

According to some exemplary embodiments, the orthographic projection of the lens on the base substrate at least partially overlaps with an orthographic projection of the light-shielding portion on the base substrate.

In another aspect, there is provided a display panel, including: the display substrate described above, a cover plate arranged opposite to the display substrate; and an adhesive layer located between the display substrate and the cover plate.

In another aspect, there is provided a method of manufacturing a display substrate, including: forming a plurality of conductive patterns on a base substrate; bonding a light-emitting element epitaxial wafer to the base substrate formed with the plurality of conductive patterns; patterning the light-emitting element epitaxial wafer to form a plurality of light-emitting elements arranged in an array and spaced apart from each other on the base substrate, where at least one light-emitting element includes a first electrode, a first type semiconductor layer, a light-emitting layer, and a second type semiconductor layer, where the first electrode is electrically connected to the conductive pattern, the first type semiconductor layer is located on a side of the first electrode away from the base substrate, the light-emitting layer is located on a side of the first type semiconductor layer away from the base substrate, and the second type semiconductor layer is located on a side of the light-emitting layer away from the base substrate; and forming a second electrode on a side of the second type semiconductor layer away from the base substrate; and forming a conductive light-shielding portion in a gap between the plurality of light-emitting elements, where the light-shielding portion is electrically connected to the second electrode.

In another aspect, there is provided a method of manufacturing a display substrate, including: forming a second light-emitting sub-element epitaxial structure on a second substrate; forming a second bonding sub-layer on a side of the second light-emitting sub-element epitaxial structure away from the second substrate; patterning the second light-emitting sub-element epitaxial structure and the second bonding sub-layer to form a second light-emitting sub-element, where the second light-emitting sub-element includes a second type semiconductor layer, a light-emitting layer, and a first type semiconductor layer, the second type semiconductor layer of the second light-emitting sub-element is located on the second substrate, the light-emitting layer of the second light-emitting sub-element is located on a side of the second type semiconductor layer of the second light-emitting sub-element away from the first substrate, and the first type semiconductor layer of the second light-emitting sub-element is located on a side of the light-emitting layer of the second light-emitting sub-element away from the first substrate; forming a first light-emitting sub-element epitaxial structure on a first substrate; forming a first bonding sub-layer on a side of the first light-emitting sub-element epitaxial structure away from the first substrate; bonding the second light-emitting sub-element and the first light-emitting sub-element epitaxial structure through the first bonding sub-layer and the second bonding sub-layer; removing the first substrate; patterning the first light-emitting sub-element epitaxial structure and the first bonding sub-layer to form a first light-emitting sub-element, where the first light-emitting sub-element includes a second type semiconductor layer, a light-emitting layer, and a first type semiconductor layer, the second type semiconductor layer of the first light-emitting sub-element is located on the first bonding sub-layer, the light-emitting layer of the first light-emitting sub-element is located on a side of the second type semiconductor layer of the first light-emitting sub-element away from the second substrate, and the first type semiconductor layer of the first light-emitting sub-element is located on a side of the light-emitting layer of the first light-emitting sub-element away from the second substrate; and bonding the second substrate formed with the first light-emitting sub-element and the second light-emitting sub-element to a base substrate, and removing the second substrate to form a plurality of light-emitting elements on the base substrate, where at least one light-emitting element includes a first light-emitting sub-element and a second light-emitting sub-element, the first light-emitting sub-element and the second light-emitting sub-element are stacked in a direction perpendicular to a first surface of the base substrate, where the first surface is a surface of the base substrate facing the light-emitting element; forming a second electrode on a side of the second type semiconductor layer of the second light-emitting sub-element away from the base substrate; and forming a conductive light-shielding portion in a gap between the plurality of light-emitting elements, where the light-shielding portion is electrically connected to the second electrode.

In another aspect, there is provided a method of manufacturing a display substrate, including: forming a second light-emitting sub-element epitaxial structure on a second substrate; forming a second bonding sub-layer on a side of the second light-emitting sub-element epitaxial structure away from the second substrate; forming a first light-emitting sub-element epitaxial structure on a first substrate; forming a first bonding sub-layer on a side of the first light-emitting sub-element epitaxial structure away from the first substrate; bonding the second light-emitting sub-element epitaxial structure and the first light-emitting sub-element epitaxial structure through the first bonding sub-layer and the second bonding sub-layer; removing the first substrate; bonding the second substrate formed with the second light-emitting sub-element epitaxial structure and the first light-emitting sub-element epitaxial structure to a base substrate, removing the second substrate, and patterning the second light-emitting sub-element epitaxial structure and the first light-emitting sub-element epitaxial structure to form a plurality of light-emitting elements on the base substrate, where at least one light-emitting element includes a first light-emitting sub-element and a second light-emitting sub-element, the first light-emitting sub-element and the second light-emitting sub-element are stacked in a direction perpendicular to a first surface of the base substrate, and the first surface is a surface of the base substrate facing the light-emitting element; forming a second electrode on a side of the second light-emitting sub-element away from the base substrate; and forming a conductive light-shielding portion in a gap between the plurality of light-emitting elements, where the light-shielding portion is electrically connected to the second electrode.

### BRIEF DESCRIPTION OF THE DRAWINGS

Other objectives and advantages of the present disclosure will become apparent by the following description of the present disclosure with reference to the accompanying drawings, which may assist in a comprehensive understanding of the present disclosure.

FIG. 1 schematically shows a schematic plan view of a display panel according to an embodiment of the present disclosure.

FIG. 2 schematically shows a schematic cross-sectional view of a display panel according to an embodiment of the present disclosure.

FIG. 3 schematically shows an inclination angle diagram of a light-emitting element according to an embodiment of the present disclosure.

FIG. 4 schematically shows a spacing diagram of a light-shielding portion and a first insulating layer projected on a base substrate according to an embodiment of the present disclosure.

FIG. 5 schematically shows a schematic cross-sectional view of a display panel according to an embodiment of the present disclosure.

FIG. 6 schematically shows a cross-sectional view of a display substrate according to an embodiment of the present disclosure.

FIG. 7 schematically shows a shape diagram of a first bonding layer according to an embodiment of the present disclosure.

FIG. 8 schematically shows a light spot effect diagram of a flip chip.

FIG. 9 schematically shows a light spot effect diagram of a display substrate according to an embodiment of the present disclosure.

FIG. 10 is a flowchart of a method of manufacturing a display substrate according to an embodiment of the present disclosure.

FIG. 11 is a schematic structure diagram of a light-emitting element epitaxial wafer according to an embodiment of the present disclosure.

FIG. 12 is a schematic structure diagram of patterning a light-emitting element epitaxial wafer according to an embodiment of the present disclosure.

FIG. 13 is a schematic diagram of a first insulating layer according to an embodiment of the present disclosure.

FIG. 14 is a schematic diagram of a second electrode according to an embodiment of the present disclosure.

FIG. 15 is a schematic diagram of a light-shielding portion according to an embodiment of the present disclosure.

FIG. 16 is a flowchart of a method of manufacturing a display substrate according to an embodiment of the present disclosure.

FIG. 17 is a schematic structure diagram of a light-emitting element epitaxial wafer according to an embodiment of the present disclosure.

FIG. 18 is a schematic structure diagram of a second bonding sub-layer according to an embodiment of the present disclosure.

FIG. 19 is a schematic structure diagram of patterning a light-emitting element epitaxial wafer according to an embodiment of the present disclosure.

FIG. 20 is a schematic structure diagram of a first temporary bonding layer according to an embodiment of the present disclosure.

FIG. 21 is a schematic diagram of bonding a first light-emitting sub-element epitaxial structure and a first substrate according to an embodiment of the present disclosure.

FIG. 22 is a schematic diagram of removing a first temporary substrate according to an embodiment of the present disclosure.

FIG. 23 is a schematic diagram of forming a first bonding sub-layer according to an embodiment of the present disclosure.

FIG. 24 is a schematic diagram of bonding a second light-emitting sub-element and a first light-emitting sub-element epitaxial structure according to an embodiment of the present disclosure.

FIG. 25 is a schematic diagram of removing a first substrate according to an embodiment of the present disclosure.

FIG. 26 is a schematic diagram of patterning a first light-emitting sub-element epitaxial structure and a first bonding sub-layer according to an embodiment of the present disclosure.

FIG. 27 is a schematic diagram of bonding a second substrate and a base substrate according to an embodiment of the present disclosure.

FIG. 28 is a schematic diagram of an insulating layer according to an embodiment of the present disclosure.

FIG. 29 is a schematic diagram of a second electrode according to an embodiment of the present disclosure.

FIG. 30 is a schematic diagram of a light-shielding portion according to an embodiment of the present disclosure.

FIG. 31 is a flowchart of another method of manufacturing a display substrate according to an embodiment of the present disclosure.

FIG. 32 is a schematic diagram of a second light-emitting sub-element epitaxial structure and a first light-emitting sub-element epitaxial structure according to an embodiment of the present disclosure.

FIG. 33 is a schematic diagram of bonding and patterning a second substrate of a second light-emitting sub-element epitaxial structure and a first light-emitting sub-element epitaxial structure and a base substrate according to an embodiment of the present disclosure.

FIG. 34 is a schematic diagram of a cover plate and an adhesive layer according to an embodiment of the present disclosure.

It should be noted that, for the sake of clarity, dimensions of layers, structures or regions in the accompanying drawings used to describe embodiments of the present disclosure may be exaggerated or reduced, i.e., the accompanying drawings are not drawn to an actual scale.

### DETAILED DESCRIPTION OF EMBODIMENTS

In the following description, for purposes of explanation, numerous specific details are set forth in order to provide a thorough understanding of the various exemplary embodiments. It is evident, however, that the various exemplary embodiments may be practiced without these specific details or with one or more equivalent arrangements. In other instances, well-known structures and devices are shown in block diagram form in order to avoid unnecessarily obscuring the various exemplary embodiments. Moreover, the various exemplary embodiments may be different, but are not necessarily exclusive. For example, the particular shapes, configurations and characteristics of the exemplary embodiments may be used or implemented in another exemplary embodiment without departing from the inventive concept.

In the accompanying drawings, a size and relative size of elements may be exaggerated for purposes of clarity and/or description. As such, the size and relative size of various elements are not necessarily limited to those shown in the figures. While exemplary embodiments may be practiced differently, the specific process sequence may be performed differently from the described sequence. For example, two consecutively described processes may be performed substantially simultaneously or in an order reverse to the order described. In addition, the same reference signs indicate the same elements.

When an element is described as being “on”, “connected to” or “coupled to” another element, the element may be directly on, connected or coupled to the another element or an intervening element may be present. However, when an element is described as being “directly on”, “directly connected to” or “directly coupled to” another element, there is no intervening element. Other terms and/or expressions used to describe a relationship between elements should be interpreted in a similar manner, such as, “between. and” versus “directly between. and”, “adjacent” versus “directly adjacent” or “on” versus “directly on”, etc. Moreover, a term “connection” may refer to a physical connection, an electrical connection, a communication connection, and/or a fluid connection. Furthermore, X, Y, and Z axes are not limited to three axes of a rectangular coordinate system, and may be interpreted in a broader sense. For example, X, Y, and Z axes may be perpendicular to each other, or may represent different directions that are not perpendicular to each other. For purposes of the present disclosure, “at least one of X, Y and Z” and “at least one selected from a group consisting of X, Y and Z” may be interpreted as X only, Y only, Z only, or any combination of two or more of X, Y and Z, such as XYZ, XY, YZ and XZ. As used herein, a term “and/or” includes any and all combinations of one or more of related items listed.

It should be understood that, although the terms first, second, etc. may be used herein to describe various elements, these elements should not be limited by these terms. These terms are only used to distinguish one element from another. For example, without departing from the scope of example embodiments, a first element could be termed a second element, and, similarly, a second element could be termed a first element.

In the present disclosure, an inorganic light-emitting diode refers to a light-emitting element made of an inorganic material, where LED represents an inorganic light-emitting element different from OLED. Specifically, the inorganic light-emitting element may include Mini Light Emitting Diode (abbreviated as Mini LED) and Micro Light Emitting Diode (abbreviated as Micro LED). Micro Light Emitting Diode (i.e., Micro LED) refers to an ultra-small LED with a grain size of less than 100 microns, while Mini Light Emitting Diode (i.e., Mini LED) refers to a small LED with a grain size between the Micro LED and a conventional LED. For example, the grain size of Mini LED may range from 50 to 400 microns. PPI (Pixels Per Inch) represents the number of pixels contained per inch.

With the development of technology, the development momentum of LED display devices is rapid, for example, micro LED display technology has begun to be applied to AR applications. The inventors find in the research that, on the one hand, in the micro LED display technology for AR applications, a PPI of 5000 or higher is usually required, and the distance between pixels is very small. Between pixels distributed at a small distance, light rays of the light-emitting elements will interfere with each other, and cross color and crosstalk between pixels will occur. If the LED is etched into a vertical structure, due to a high refractive index of GaN, a critical angle in air is only 25 degrees, that is, light within 25° oscillates repeatedly in the structure, and may not effectively emitted out of the device to achieve display brightness.

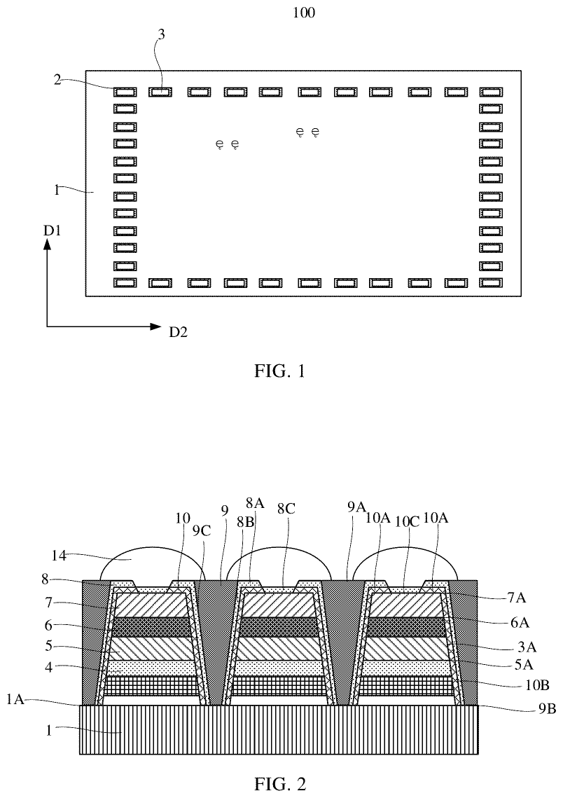

FIG. 1 schematically shows a schematic plan view of a display panel according to an embodiment of the present disclosure.

Referring to FIG. 1, the display substrate 100 may include a base substrate 1, a plurality of conductive patterns 2 located on the base substrate 1, and a plurality of light-emitting elements 3 located on the base substrate 1. The plurality of light-emitting elements 3 are arranged in an array and spaced apart from each other on the base substrate 1, and an orthographic projection of each light-emitting element 3 on the base substrate 1 at least partially overlaps with an orthographic projection of the conductive pattern 2 on the base substrate.

For example, the material of the base substrate 1 may include but is not limited to glass, quartz, plastic, silicon, polyimide, and the like.

In the exemplary embodiment of FIG. 1, a first direction D1 and a second direction D2 are schematically shown, for example, the plurality of light-emitting elements 3 may be arranged in an array in the first direction D1 and the second direction D2. It should be noted that the embodiments of the present disclosure are not limited to this.

FIG. 2 schematically shows a schematic cross-sectional view of a display panel according to an embodiment of the present disclosure.

Referring to FIG. 2, at least one light-emitting element 3 includes a first electrode 4, a first type semiconductor layer 5, a light-emitting layer 6, a second type semiconductor layer 7, and a second electrode 8, where the first electrode 4 is electrically connected to the conductive pattern 2, the first type semiconductor layer 5 is located on a side of the first electrode 4 away from the base substrate 1, the light-emitting layer 6 is located on a side of the first type semiconductor layer 5 away from the base substrate 1, the second type semiconductor layer 7 is located on a side of the light-emitting layer 6 away from the base substrate 1, and the second electrode 8 is located on a side of the second type semiconductor layer 7 away from the base substrate 1, and a conductive light-shielding portion 9 located on the base substrate 1, where the light-shielding portion 9 is located in a gap between two adjacent light-emitting elements 3, and is electrically connected to the second electrode 8.

For example, the first electrode 4 may be an electrode formed of a transparent conductive material. The first type semiconductor layer 5 may be an N-type semiconductor, such as N-type gallium nitride (GaN), denoted as N—GaN. The second electrode 8 may be an electrode formed of a transparent conductive material. The second type semiconductor layer 7 may be a P-type semiconductor, P-type gallium nitride (GaN), denoted as P—GaN.

The material of the light-shielding portion 9 is a metal material with good conductivity, including but not limited to copper, aluminum, tin or other alloy materials.

In the embodiments of the present disclosure, the light-emitting layer 6 includes a top surface 6A away from the base substrate 1, the light-shielding portion 9 includes a top surface 9A away from the base substrate 1, and the base substrate 1 includes a first surface 1A facing the light-emitting element 3. The height of the top surface 9A of the light-shielding portion 9 relative to the first surface 1A is greater than the height of the top surface of the light-emitting layer 6 relative to the first surface 1A.

In the embodiments of the present disclosure, the second type semiconductor layer 7 includes a top surface 7A away from the base substrate 1, and the height of the top surface 9A of the light-shielding portion 9 relative to the first surface 1A is greater than the height of the top surface 7A of the second type semiconductor layer 7 relative to the first surface 1A.

In the embodiments of the present disclosure, the first type semiconductor layer 5 includes a bottom surface 5A close to the base substrate 1, the light-shielding portion 9 includes a bottom surface 9B close to the base substrate 1, and the height of the bottom surface 9B of the light-shielding portion 9 relative to the first surface 1A is less than the height of the bottom surface 5A of the first type semiconductor layer 5 relative to the first surface 1A.

In the embodiments of the present disclosure, the bottom surface 9B of the light-shielding portion 9 is in contact with the first surface 1A.

In the embodiments of the present disclosure, the first type semiconductor layer 5 includes a bottom surface 5A close to the base substrate 1, the light-emitting element 3 includes a sidewall 3A connecting the top surface 7A of the second type semiconductor layer 7 and the bottom surface 5A of the first type semiconductor layer 5, and the sidewall 3A of the light-emitting element 3 is inclined relative to the bottom surface 5A of the first type semiconductor layer 5.

In the embodiments of the present disclosure, the light-shielding portion 9 includes a bottom surface 9B close to the base substrate 1, and a sidewall 9C connecting the top surface 9A of the light-shielding portion 9 and the bottom surface of the light-shielding portion 9, and the sidewall 9C of the light-shielding portion 9 is inclined relative to the bottom surface 9B of the light-shielding portion 9.

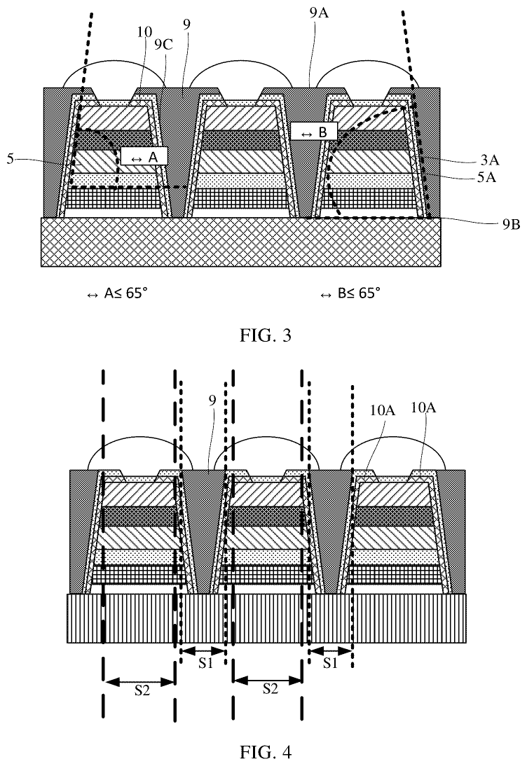

FIG. 3 schematically shows an inclination angle diagram of a light-emitting element according to an embodiment of the present disclosure.

In the embodiments of the present disclosure, the sidewall 3A of the light-emitting element 3 is inclined at a first angle ∠A relative to the bottom surface 5A of the first type semiconductor layer 5, and the first angle ∠A is less than or equal to 65°; and/or, the sidewall 9C of the light-shielding portion 9 is inclined at a second angle ∠B relative to the bottom surface 9B of the light-shielding portion 9, and the second angle ∠B is less than or equal to 65°. The inventors find in the research that if the LED is etched into a vertical structure, due to a high refractive index of GaN, a critical angle in air is only 25 degrees, that is, light within 25°oscillates repeatedly in the structure, and may not effectively emitted out of the device to achieve display brightness. As shown in FIG. 3, the light-emitting element forms an obverse trapezoid with a first angle ∠A of less than or equal to 65°, which is beneficial for breaking through the limitation of the critical angle and allowing the light to come out more effectively.

With continued reference to FIG. 2, the display panel further includes a first insulating layer 10 located between the second type semiconductor layer 7 and a layer where the second electrode 8 is located, and a plurality of openings 10C located in the first insulating layer 10. The first insulating layer 10 includes a first portion 10A and a second portion 10B. The first portion 10A of the first insulating layer 10 covers a part of the top surface 7A of the second type semiconductor layer 7, the opening 10C exposes another part of the top surface 7A of the second type semiconductor layer 7, and the second portion 10B of the first insulating layer 10 covers the sidewall 3A of the light-emitting element 3. For example, the first insulating layer 10 may be made of an inorganic material having a gradually changing refractive index, such as silicon nitride or silicon oxide, and the refractive index of the first insulating layer 10 may satisfy a gradual change from the refractive index of GaN to the refractive index of air. Specifically, the refractive index of GaN is 2.4, the refractive index of air is 1.0, and the refractive index of the first insulating layer 10 may be between 2.4 and 1.0 to satisfy the gradual change from the refractive index of GaN to the refractive index of air.

In the embodiments of the present disclosure, the second electrode 8 includes a first electrode portion 8A, a second electrode portion 8B, and a third electrode portion 8C. The first electrode portion 8A covers the first portion 10A of the first insulating layer 10, the second electrode portion 8B covers the second portion 10B of the first insulating layer 10, and the third electrode portion 8C is located in the opening 10C. The light-shielding portion 9 is in contact with at least the first electrode portion 8A of the second electrode 8. Due to the second electrode of at least one light-emitting element being connected together by a light-shielding portion with good conductivity, the voltage drop (IR drop) in the display substrate may be effectively reduced.

FIG. 4 schematically shows a spacing diagram of a light-shielding portion and a first insulating layer projected on a base substrate according to an embodiment of the present disclosure.

As shown in FIG. 4, an orthographic projection S1 of the light-shielding portion 9 on the base substrate 1 is spaced apart from an orthographic projection S2 of the second portion 10B of the first insulating layer 10 on the base substrate 1.

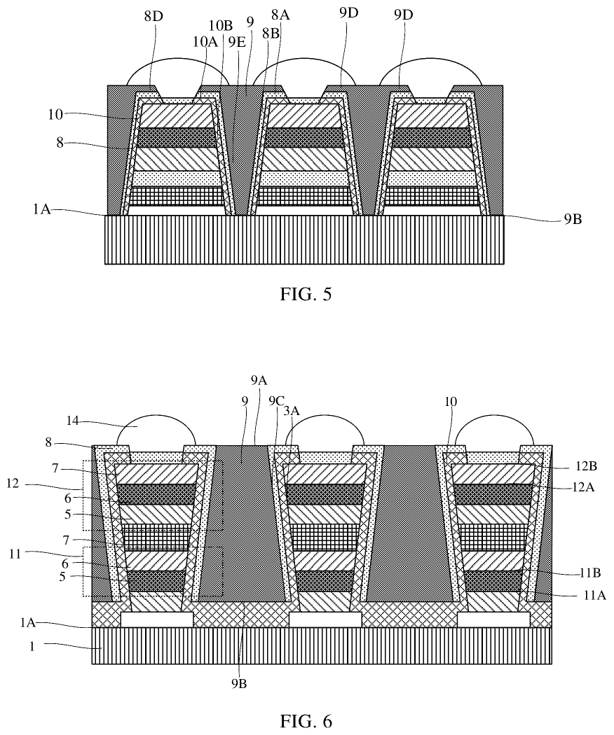

FIG. 5 schematically shows a spacing diagram of a light-shielding portion and a first insulating layer projected on a base substrate according to an embodiment of the present disclosure.

In the embodiments of the present disclosure, as shown in FIG. 5, the light-shielding portion 9 further includes a first light-shielding sub-portion 9D and a second light-shielding sub-portion 9E. The first light-shielding sub-portion 9D is in contact with the first electrode portion 8A of the second electrode 8, and the second light-shielding sub-portion 9E is in contact with the second electrode portion 8B of the second electrode 8.

Referring to FIG. 5, an orthographic projection of the second light-shielding sub-portion 9E on the base substrate 1 at least partially overlaps with an orthographic projection of the second electrode portion 8B of the second electrode 8 on the base substrate 1; and/or, the orthographic projection of the second light-shielding sub-portion 9E on the base substrate 1 at least partially overlaps with an orthographic projection of the second portion 10B of the first insulating layer 10 on the base substrate 1. The second electrode 8 includes a top surface 8D away from the base substrate 1, and the height of the top surface 9A of the light-shielding portion 9 relative to the first surface 1A is greater than the height of the top surface 8D of the second electrode 8 relative to the first surface 1A.

According to the embodiments of the present disclosure, the contact surface between the light-shielding portion and the second electrode is larger, and only at the opening left by the insulating layer in a light output direction, the light-shielding portion does not contact the second electrode, which may effectively reduce the voltage drop in the display substrate.

At present, various display technologies are comprehensively compared. On the one hand, the power consumption of LED display is high, and in order to reduce the power consumption level of the LED display, it is necessary to study the power consumption composition of the LED display, and its static mini LED display power consumption consists of TFT power consumption (transistor power consumption), IR drop power consumption (voltage drop power consumption), and LED power consumption. In order to reduce the power consumption loss of the display, it is necessary to increase the power consumption ratio of effective LEDs to improve chip efficiency and ensure its photoelectric conversion performance. On the other hand, as shown in FIG. 8, when a flip chip is used, congestion and blockage are prone to occur due to current expansion, and hence the light spot uniformity is poor, the current controllability is poor, and the light pattern is asymmetric and difficult to control.

FIG. 6 schematically shows a cross-sectional view of a display substrate according to an embodiment of the present disclosure.

As shown in FIG. 6, at least one light-emitting element 3 includes a first light-emitting sub-element 11 and a second light-emitting sub-element 12, and the first light-emitting sub-element 11 and the second light-emitting sub-element 12 are stacked in a direction perpendicular to the first surface 1A of the base substrate 1, and the first surface 1A is a surface of the base substrate 1 facing the light-emitting element 3.

According to the embodiments of the present disclosure, the first light-emitting sub-element 11 includes a first electrode 4, a first type semiconductor layer 5, a light-emitting layer 6, and a second type semiconductor layer 7. The first electrode 4 is electrically connected to the conductive pattern 2, the first type semiconductor layer 5 of the first light-emitting sub-element 11 is located on a side of the first electrode 4 away from the base substrate 1, the light-emitting layer 6 of the first light-emitting sub-element 11 is located on a side of the first type semiconductor layer 5 of the first light-emitting sub-element 11 away from the base substrate 1, and the second type semiconductor layer 7 of the first light-emitting sub-element 11 is located on a side of the light-emitting layer 6 of the first light-emitting sub-element 11 away from the base substrate 1.

According to the embodiments of the present disclosure, the second light-emitting sub-element 12 includes a first type semiconductor layer 5, a light-emitting layer 6, a second type semiconductor layer 7, and a second electrode 8. The first type semiconductor layer 5 of the second light-emitting sub-element 12 is located on a side of the second type semiconductor layer 7 of the first light-emitting sub-element 11 away from the base substrate 1, the light-emitting layer 6 of the second light-emitting sub-element 12 is located on a side of the first type semiconductor layer 5 of the second light-emitting sub-element 12 away from the base substrate 1, the second type semiconductor layer 7 of the second light-emitting sub-element 12 is located on a side of the light-emitting layer 6 of the second light-emitting sub-element 12 away from the base substrate 1, and the second electrode 8 is located on a side of the second type semiconductor layer 7 of the second light-emitting sub-element 12 away from the base substrate 1. The second type semiconductor layer 7 of the first light-emitting sub-element 11 and the first type semiconductor layer 5 of the second light-emitting sub-element 12 are electrically connected through the first bonding layer 13.

According to the embodiments of the present disclosure, the light-emitting layer 6 of the second light-emitting sub-element 12 includes a top surface 12A away from the base substrate 1, the light-shielding portion 9 includes a top surface 9A away from the base substrate 1, and the height of the top surface 9A of the light-shielding portion 9 relative to the first surface 1A is greater than the height of the top surface 12A of the light-emitting layer 6 of the second light-emitting sub-element 12 relative to the first surface 1A; and/or, the light-emitting layer 6 of the first light-emitting sub-element 11 includes a bottom surface 11B close to the base substrate 1, the light-shielding portion 9 includes a bottom surface 9B close to the base substrate 1, and the height of the bottom surface 9B of the light-shielding portion 9 relative to the first surface 1A is less than the height of the bottom surface 11B of the light-emitting layer 6 of the first light-emitting sub-element 11 relative to the first surface 1A.

According to the embodiments of the present disclosure, the second type semiconductor layer 7 of the second light-emitting sub-element 12 includes a top surface 12B away from the base substrate 1, and the height of the top surface 9A of the light-shielding portion 9 relative to the first surface 1A is greater than the height of the top surface 12B of the second type semiconductor layer 7 of the second light-emitting sub-element 12 relative to the first surface 1A; and/or, the first type semiconductor layer 5 of the first light-emitting sub-element 11 includes a bottom surface 11A close to the base substrate 1, and the height of the bottom surface 9B of the light-shielding portion 9 relative to the first surface 1A is less than the height of the bottom surface 11A of the first type semiconductor layer 5 of the first light-emitting sub-element 11 relative to the first surface 1A.

According to the embodiments of the present disclosure, the bottom surface 9B of the light-shielding portion 9 is in contact with the first surface 1A.

According to the embodiments of the present disclosure, the light-emitting element 3 includes a sidewall 3A connecting the top surface 12B of the second type semiconductor layer 7 of the second light-emitting sub-element 12 and the bottom surface 11A of the first type semiconductor layer 5 of the first light-emitting sub-element 11. The sidewall 3A of the light-emitting element 3 is inclined relative to the bottom surface 11A of the first type semiconductor layer 5 of the first light-emitting sub-element 11.

According to the embodiments of the present disclosure, the light-shielding portion 9 includes a bottom surface 9B close to the base substrate 1, and a sidewall connecting the top surface 9A of the light-shielding portion 9 and the bottom surface of the light-shielding portion 9. The sidewall 9C of the light-shielding portion 9 is inclined relative to the bottom surface 9B of the light-shielding portion 9.

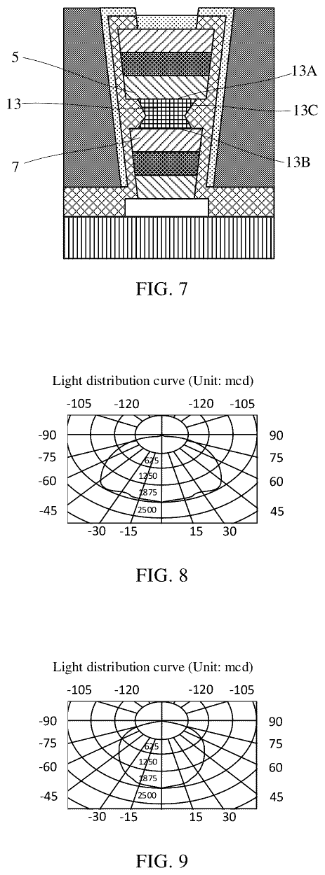

FIG. 7 schematically shows a shape diagram of a first bonding layer according to an embodiment of the present disclosure.

In an actual manufacturing process, due to process and other reasons, due to differences in etching deviations of the epitaxy of the first light-emitting sub-element, the epitaxy of the second light-emitting sub-element, and the first bonding layer, the first bonding layer 13 may be inwardly recessed. Referring to FIG. 7, the first bonding layer 13 includes a bottom surface 13A of the second type semiconductor layer 7 facing the first light-emitting sub-element 11, a top surface 13B of the first type semiconductor layer 5 facing the second light-emitting sub-element 12, and a sidewall 13C connecting the bottom surface of the first bonding layer 13 and the top surface of the first bonding layer 13. The sidewall 13C of the first bonding layer 13 is inwardly recessed relative to the sidewall of the second type semiconductor layer 7 of the adjacent first light-emitting sub-element 11, and/or the sidewall 13A of the first bonding layer 13 is inwardly recessed relative to the sidewall of the first type semiconductor layer 5 of the adjacent second light-emitting sub-element 12.

Referring back to FIG. 2 and FIG. 5, the display substrate 100 further includes a lens 14 located on the base substrate 1. The lens 14 is located on a side of the second electrode 8 away from the base substrate 1. An orthographic projection of the lens 14 on the base substrate 1 covers an orthographic projection of the opening 10C on the base substrate 1.

It should be noted that in some embodiments, the orthographic projection of the lens 14 on the base substrate 1 at least partially overlaps with the orthographic projection of the second portion 10B of the first insulating layer 10 on the base substrate 1; and/or, the orthographic projection of the lens 14 on the base substrate 1 at least partially overlaps with the orthographic projection of the second electrode portion 8B of the second electrode 8 on the base substrate 1. The orthographic projection of the lens 14 on the base substrate 1 at least partially overlaps with the orthographic projection of the light-shielding portion 9 on the base substrate 1.

The first light-emitting sub-element and the second light-emitting sub-element in the light-emitting element are stacked, and the first type semiconductor layer and the second type semiconductor layer in the light-emitting sub-element are stacked, so that the current expansibility is higher, the recombination degree of electrons and holes is better, and a more uniform light pattern such as shown in FIG. 9 may be obtained.

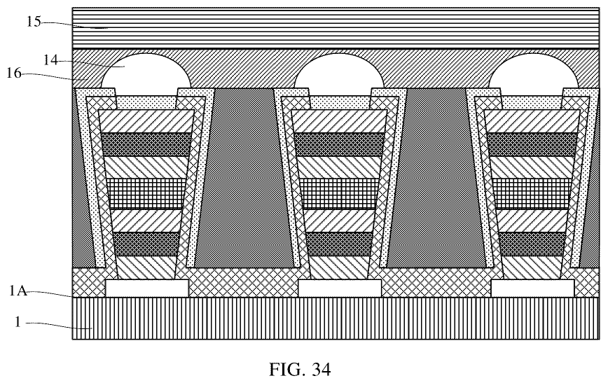

In some embodiments, referring to FIG. 34, the display panel includes a display substrate 100, a cover plate 15 arranged opposite to the display substrate 100, and an adhesive layer 16 located between the display substrate 100 and the cover plate 15. As shown in FIG. 34, the side of the cover plate 15 close to the light-emitting element is the first bottom surface of the cover plate 15, and the point where the lens 14 is farthest from the base substrate 1 is the vertex of the lens 14. The distance between the first bottom surface and the first surface 1A of the base substrate 1 is greater than the distance between the vertex of the lens 14 and the first surface 1A of the base substrate 1. The material used for the cover plate 15 includes but are not limited to glass, silicon, etc. The adhesive layer 16 between the cover plate 15 and the display substrate 100 includes but is not limited to OCR (Optical Clear Resin) adhesive, OCA (Optical Clear Adhesive) adhesive, and the like.

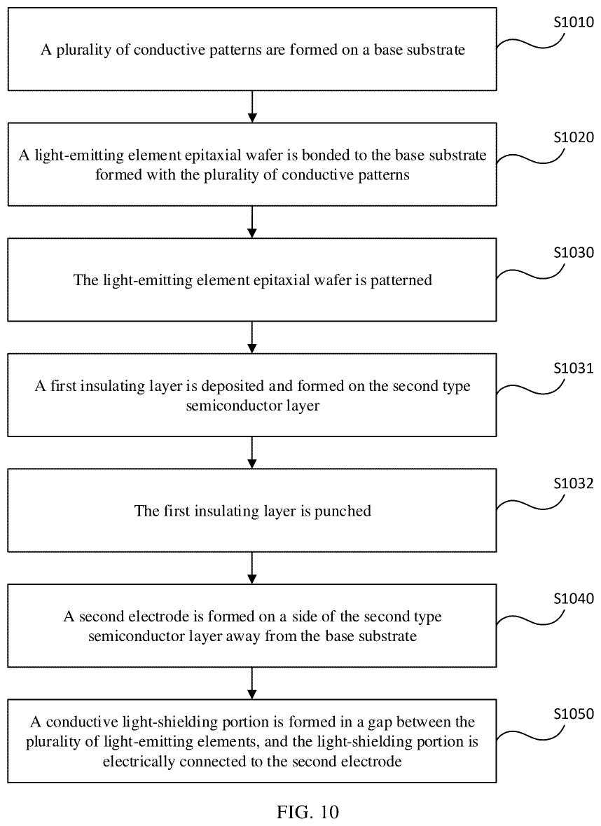

FIG. 10 is a flowchart of a method of manufacturing a display substrate according to an embodiment of the present disclosure. As shown in FIG. 10, the method may include step S1010 to step S1050.

In step S1010, a substrate 1 is provided, and a plurality of conductive patterns 2 are formed on the base substrate 1. The material of the base substrate 1 may include but is not limited to glass, quartz, plastic, silicon, polyimide, and the like.

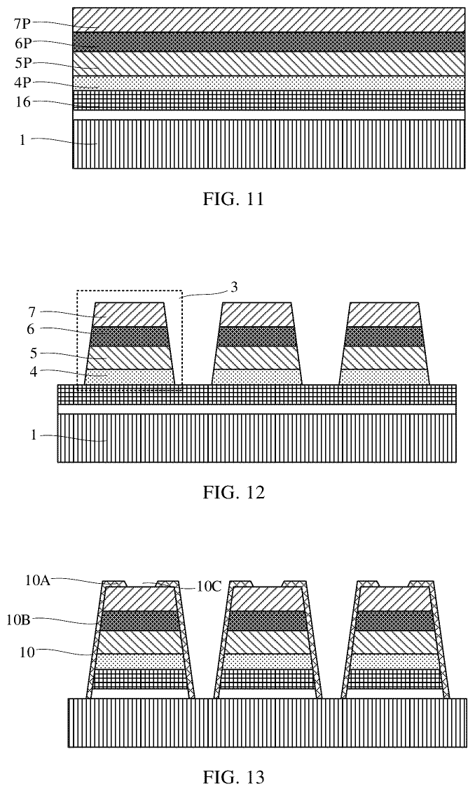

In step S1020, the light-emitting element epitaxial wafer is bonded to the base substrate formed with the plurality of conductive patterns 2. As shown in FIG. 11, the light-emitting element epitaxial wafer includes a first electrode epitaxy 4P, a first type semiconductor epitaxy 5P, a light-emitting layer epitaxy 6P, and a second type semiconductor epitaxy 7P. The light-emitting layer epitaxy 6P is located between the first type semiconductor epitaxy 5P and the second type semiconductor epitaxy 7P. The light-emitting element epitaxial wafer is bonded to the base substrate 1 formed with the plurality of conductive patterns through the bonding layer 16. The first type semiconductor epitaxy may be N-type gallium nitride (GaN), denoted as N—GaN, and the second type semiconductor epitaxy may be P-type gallium nitride (GaN), denoted as P—GaN. The bonding layer 16 may be made of metal oxide, and preferably, the material may be transparent material such as ITO (indium tin oxide), IZO (indium zinc oxide), ZnO (zinc oxide), and the like. For example, the bonding layer 16 on the P—GaN side may use ITO (indium tin oxide). The bonding layer 16 may be an entire surface or patterned.

In step S1030, the light-emitting element epitaxial wafer is patterned to form a plurality of light-emitting elements 3 arranged in an array and spaced apart from each other on the base substrate. As shown in FIG. 12, at least one light-emitting element 3 includes a first electrode 4, a first type semiconductor layer 5, a light-emitting layer 6, and a second type semiconductor layer 7. The first electrode 4 is electrically connected to the conductive pattern, the first type semiconductor layer 5 is located on a side of the first electrode 4 away from the base substrate 1, the light-emitting layer 6 is located on a side of the first type semiconductor layer 5 away from the base substrate 1, and the second type semiconductor layer 7 is located on a side of the light-emitting layer 6 away from the base substrate 1.

In some embodiments, the sidewall of the light-emitting element 3 is inclined at a first angle relative to the bottom surface of the first type semiconductor layer 5, and the first angle is less than or equal to 65°.

In step S1031, a first insulating layer 10 is deposited and formed on the second type semiconductor layer 7. For example, the material of the first insulating layer 10 may include but is not limited to SiN (silicon nitride) or SiOn (silicon oxide) material, and the like. The refractive index of the first insulating layer satisfies a gradual change ranging from 2.4 to 1.0 from the refractive index of GaN to the refractive index of air. The first insulating layer 10 covers the sidewall and the top of the light-emitting element 3.

In step S1032, the first insulating layer 10 is punched. As shown in FIG. 13, the first insulating layer 10 includes a first portion 10A and a second portion 10B. The first portion 10A of the first insulating layer 10 covers a part of the top surface of the second type semiconductor layer 7, and the opening 10C exposes another part of the top surface of the second type semiconductor layer 7. The second portion 10B of the first insulating layer 10 covers the sidewall of the light-emitting element 3. The orthographic projection of the light-shielding portion 9 on the base substrate is spaced apart from the orthographic projection of the second portion 10B of the first insulating layer 10 on the base substrate.

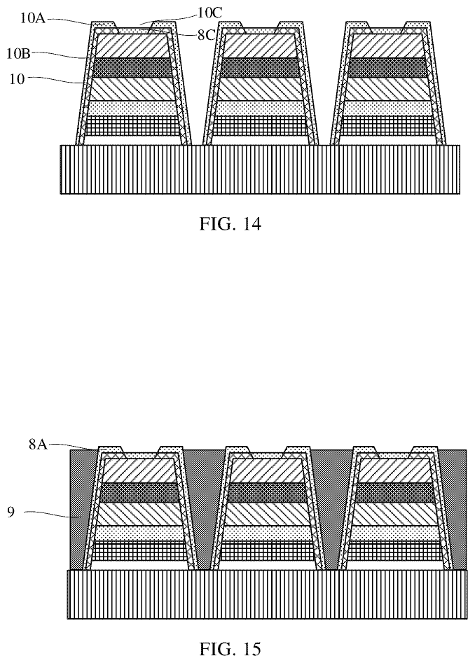

In step S1040, a second electrode 8 is formed on a side of the second type semiconductor layer 7 away from the base substrate 1. As shown in FIG. 14, the second electrode 8 includes a first electrode portion 8A, a second electrode portion 8B, and a third electrode portion 8C, and the light-shielding portion 9 is in contact with at least the first electrode portion 8A of the second electrode 8. The first electrode portion 8A of the second electrode 8 covers the first portion 10A of the first insulating layer 10, the second electrode portion 8B covers the second portion 10B of the first insulating layer 10, and the third electrode portion 8C is located in the opening 10C.

In step S1050, a conductive light-shielding portion is formed in a gap between the plurality of light-emitting elements, and the light-shielding portion is electrically connected to the second electrode. As shown in FIG. 15, the light-shielding portion 9 is in contact with at least the first electrode portion 8A of the second electrode.

In some embodiments, the light-shielding portion 9 further includes a first light-shielding sub-portion and a second light-shielding sub-portion. The first light-shielding sub-portion is in contact with the first electrode portion 8A of the second electrode 8, and the second light-shielding sub-portion is in contact with the second electrode portion 8B of the second electrode 8. An orthographic projection of the second light-shielding sub-portion on the base substrate 1 at least partially overlaps with an orthographic projection of the second electrode portion 8B of the second electrode 8 on the base substrate 1. The second electrode 8 includes a top surface away from the base substrate, and the height of the top surface of the light-shielding portion 9 relative to the first surface 1A is greater than the height of the top surface of the second electrode 8 relative to the first surface 1A. The material of the light-shielding portion 9 is a metal material with good conductivity, including but not limited to copper, aluminum, tin or other alloy materials.

For example, a dry etching method may be used to punch the first insulating layer 10.

In some embodiments, the orthographic projection of the second light-shielding sub-portion on the base substrate 1 at least partially overlaps with the orthographic projection of the second portion 10B of the first insulating layer 10 on the base substrate 1.

In some embodiments, the above-mentioned method further includes step S1060 of forming a lens over a plurality of light-emitting elements. Referring back to FIG. 2, the lens is semi-circular, and the aperture of the lens is determined by the number and pitch size of pixels. The material may be an inorganic material such as SiN, SiO, or the like, or an organic resin material or the like.

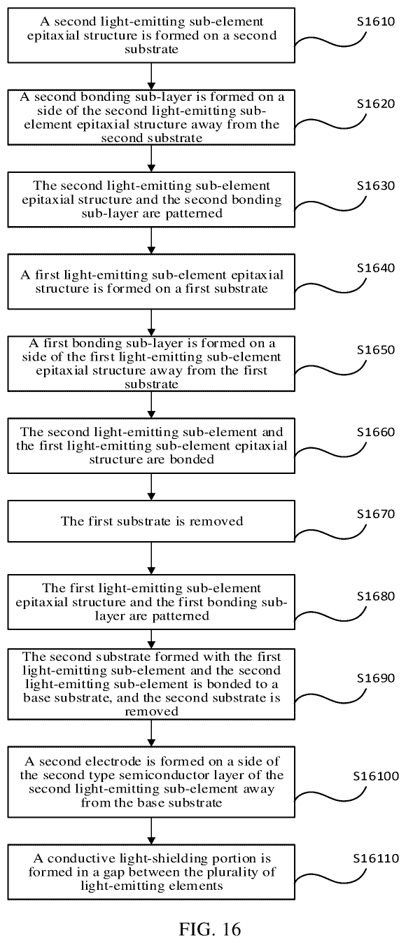

FIG. 16 is a flowchart of a method of manufacturing a display substrate according to an embodiment of the present disclosure.

As shown in FIG. 16, the method of manufacturing a display substrate according to an embodiment of the present disclosure includes step S1610 to step S16110.

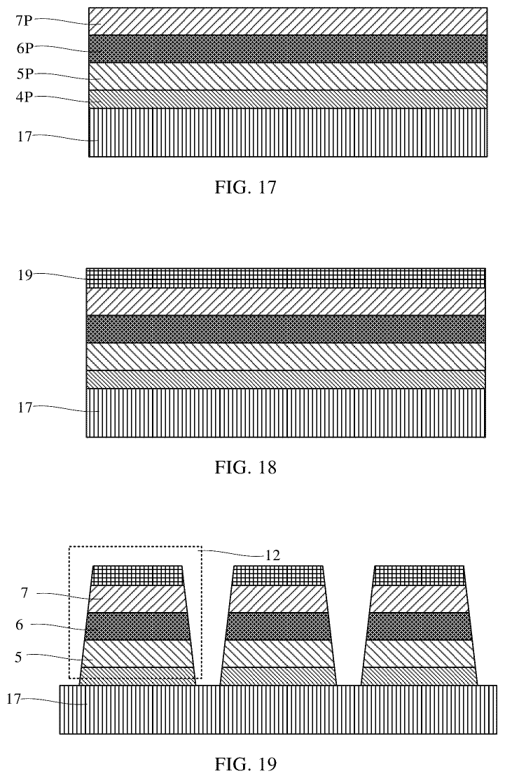

In step S1610, a second light-emitting sub-element epitaxial structure is formed on the second substrate 17. As shown in FIG. 17, the second light-emitting sub-element epitaxial structure may include a first type semiconductor layer epitaxy 5P, a light-emitting layer epitaxy 6P, and a second type semiconductor layer epitaxy 7P. The light-emitting layer epitaxy 6P is located between the first type semiconductor layer epitaxy 5P and the second type semiconductor layer epitaxy 7P. The material of the second substrate 17 may include but is not limited to glass, quartz, plastic, silicon, polyimide, and the like. The first type semiconductor layer epitaxy 5P may be N-type gallium nitride (GaN), denoted as N—GaN, and the second type semiconductor layer epitaxy 7P may be P-type gallium nitride (GaN), denoted as P—GaN.

In some embodiments, the second light-emitting sub-element epitaxial structure may further include a buffer semiconductor layer 18.

In step S1620, as shown in FIG. 18, a second bonding sub-layer 19 is formed on a side of the second light-emitting sub-element epitaxial structure away from the second substrate 17. The material of the second bonding sub-layer 19 may be a metal oxide such as ITO (indium tin oxide) or IZO (indium zinc oxide). For example, the p—GaN side bonding layer material is ITO (indium tin oxide).

In step S1630, the second light-emitting sub-element epitaxial structure and the second bonding sub-layer 19 are patterned to form the second light-emitting sub-element 12. As shown in FIG. 19, the second light-emitting sub-element 12 includes a second type semiconductor layer 7, a light-emitting layer 6, and a first type semiconductor layer 5. The second type semiconductor layer 7 of the second light-emitting sub-element 12 is located on the second substrate 17, the light-emitting layer 6 of the second light-emitting sub-element 12 is located on a side of the second type semiconductor layer 7 of the second light-emitting sub-element 12 away from the second substrate 17, and the first type semiconductor layer 5 of the second light-emitting sub-element 12 is located on a side of the light-emitting layer 6 of the second light-emitting sub-element 12 away from the second substrate 17.

In step S1640, the epitaxial structure of the first light-emitting sub-element 11 is formed on the first substrate 20.

In step S1640, step S1641 to step S1644 are specifically included.

In step S1641, a first light-emitting sub-element epitaxial structure is formed on the first temporary substrate 21.

In some embodiments, the first light-emitting sub-element epitaxial structure may be the same as the above-mentioned second light-emitting sub-element epitaxial structure.

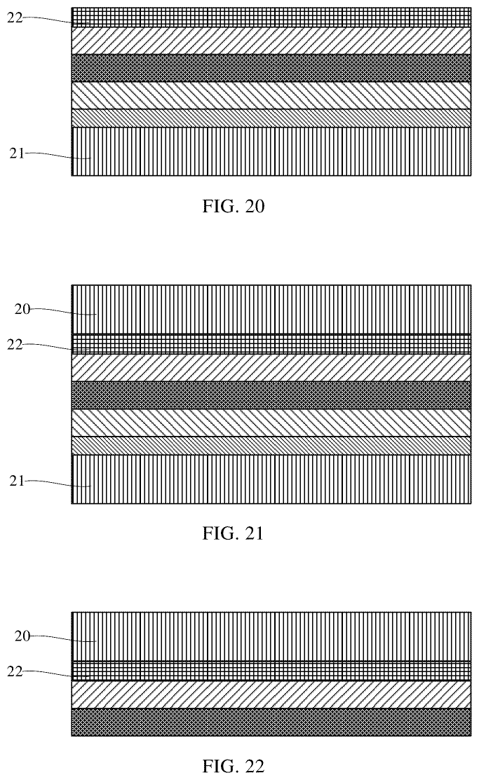

In step S1642, a first temporary bonding layer 22 is formed on the first light-emitting sub-element epitaxial structure. As shown in FIG. 20, the first temporary bonding layer 22 is located on a side of the first light-emitting sub-element epitaxial structure away from the first temporary substrate 21. The material of the first temporary bonding layer 22 may include but is not limited to SiOx (silicon oxide), and the like.

In step S1643, the first light-emitting sub-element epitaxial structure is bonded to the first substrate 20 through the first temporary bonding layer 22. As shown in FIG. 21, after the first light-emitting sub-element epitaxial structure is bonded to the first substrate 20, the first substrate 20 is located on a side of the first light-emitting sub-element epitaxial structure away from the first temporary substrate 21. The material of the first substrate 20 may include but is not limited to glass, quartz, plastic, silicon, polyimide, and the like.

In step S1644, as shown in FIG. 22, the first temporary substrate 21 is removed. It should be noted that in some embodiments, when the first light-emitting sub-element epitaxial structure includes a buffer semiconductor layer, the buffer semiconductor layer also needs to be removed.

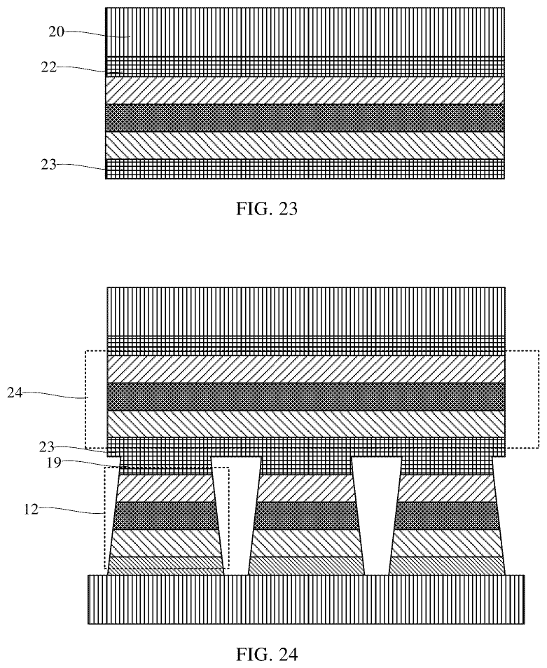

In step S1650, as shown in FIG. 23, a first bonding sub-layer 23 is formed on the side of the first light-emitting sub-element epitaxial structure away from the first substrate 20. The material of the first bonding sub-layer 23 may be metal oxides such as ITO (indium tin oxide) or IZO (indium zinc oxide). For example, the p—GaN side bonding layer material is ITO (indium tin oxide).

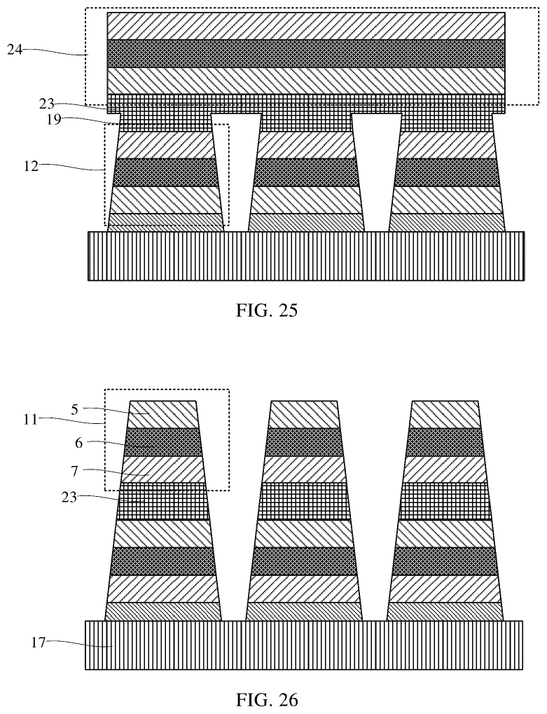

In step S1660, as shown in FIG. 24, the second light-emitting sub-element 12 and the first light-emitting sub-element epitaxial structure 24 are bonded through the first bonding sub-layer 23 and the second bonding sub-layer 19.

In step S1670, as shown in FIG. 25, the first substrate is removed. It should be noted that the first temporary bonding layer 22 also needs to be removed at the same time as the first substrate is removed.

In step S1680, the first light-emitting sub-element epitaxial structure and the first bonding sub-layer 23 are patterned to form the first light-emitting sub-element 11. As shown in FIG. 26, the first light-emitting sub-element 11 includes a second type semiconductor layer 7, a light-emitting layer 6, and a first type semiconductor layer 5. The second type semiconductor layer 7 of the first light-emitting sub-element 11 is located on the first bonding sub-layer 23, the light-emitting layer 6 of the first light-emitting sub-element 11 is located on a side of the second type semiconductor layer 7 of the first light-emitting sub-element 11 away from the second substrate 17, and the first type semiconductor layer 5 of the first light-emitting sub-element 11 is located on a side of the light-emitting layer 6 of the first light-emitting sub-element 11 away from the second substrate 17.

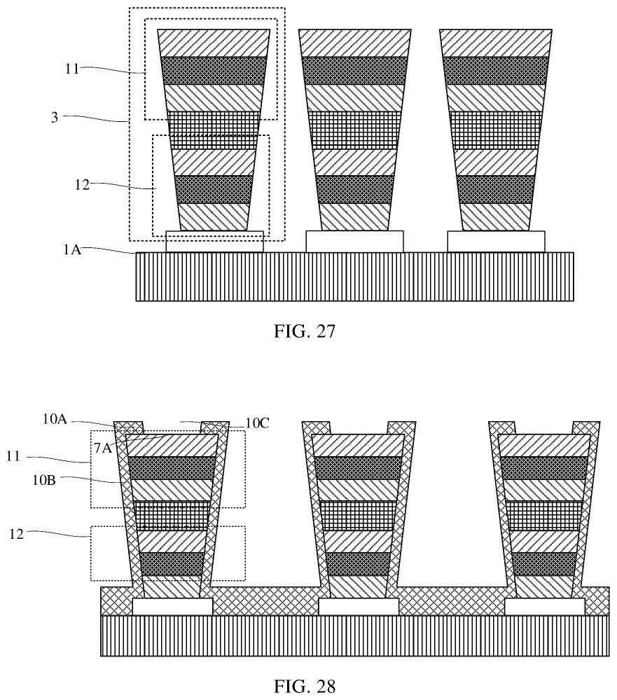

In step S1690, the second substrate 17 formed with the first light-emitting sub-element 11 and the second light-emitting sub-element 12 is bonded to the base substrate 1, and the second substrate 17 is removed to form a plurality of light-emitting elements 3 on the base substrate 1. As shown in FIG. 27, at least one light-emitting element 3 includes a first light-emitting sub-element 11 and a second light-emitting sub-element 12, and the first light-emitting sub-element 11 and the second light-emitting sub-element 12 are stacked in a direction perpendicular to the first surface 1A of the base substrate 1. The first surface 1A is a surface of the base substrate 1 facing the light-emitting element.

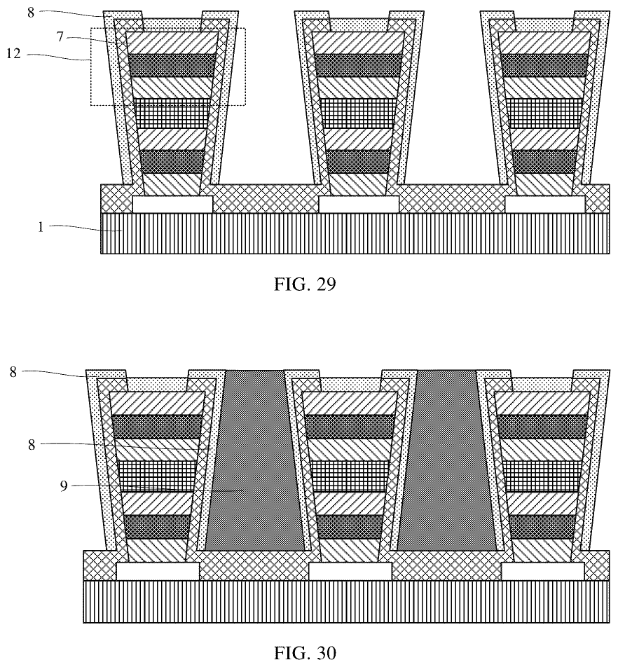

In step S16100, as shown in FIG. 29, a second electrode 8 is formed on a side of the second type semiconductor layer 7 of the second light-emitting sub-element 12 away from the base substrate 1.

In some embodiments, prior to step S16100, the method further includes fabricating an insulating layer 10, as shown in FIG. 28. The insulating layer 10 includes a first portion 10A, a second portion 10B, and an opening 10C. The first portion 10A of the insulating layer 10 covers a part of the top surface 7A of the second type semiconductor layer 7 of the first light-emitting sub-element 11, and the opening 10C exposes another part of the top surface 7A of the second type semiconductor layer 7 of the first light-emitting sub-element 11. The second portion 10B of the insulating layer 10 covers the sidewall of the first light-emitting sub-element 11 and the sidewall of the second light-emitting sub-element 12.

In step S16110, as shown in FIG. 30, a conductive light-shielding portion 9 is formed in a gap between the plurality of light-emitting elements 3, and the light-shielding portion 9 is electrically connected to the second electrode 8.

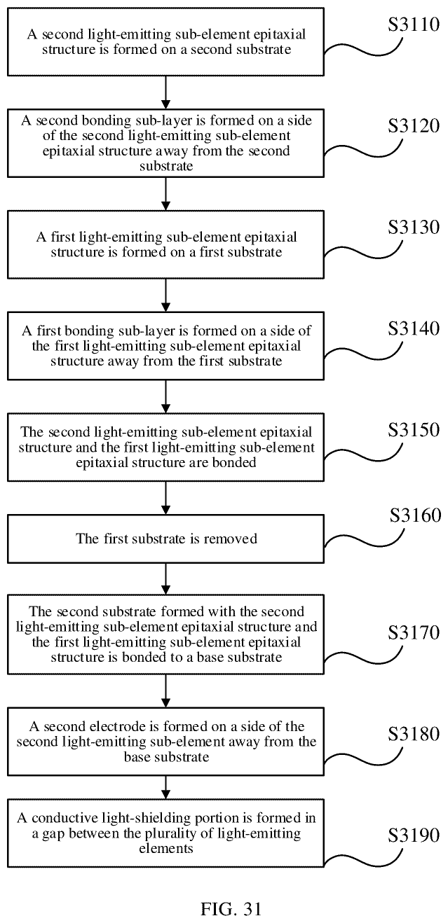

FIG. 31 is a flowchart of a method of manufacturing a display substrate according to an embodiment of the present disclosure.

As shown in FIG. 31, the method of manufacturing a display substrate according to an embodiment of the present disclosure includes step S3110 to step S3190.

In step S3110, the epitaxial structure of the second light-emitting sub-element 12 is formed on the second substrate 17, and the specific content is the same as step S1610 in the method of manufacturing a display substrate according to an embodiment of the present disclosure, and will not be described in details here.

In step S3120, a second bonding sub-layer 19 is formed on a side of the epitaxial structure of the second light-emitting sub-element 12 away from the second substrate 17, and the specific content is the same as step S1620 in the method of manufacturing a display substrate according to an embodiment of the present disclosure, and will not be described in details here.

In step S3130, a first light-emitting sub-element epitaxial structure is formed on the first substrate 20, and the specific content is the same as step S1640 in the method of manufacturing a display substrate according to an embodiment of the present disclosure, and will not be described in details here.

In step S3140, a first bonding sub-layer 23 is formed on a side of the first light-emitting sub-element epitaxial structure away from the first substrate 20, and the specific content is the same as step S1650 in the method of manufacturing a display substrate according to an embodiment of the present disclosure, and will not be described in details here.

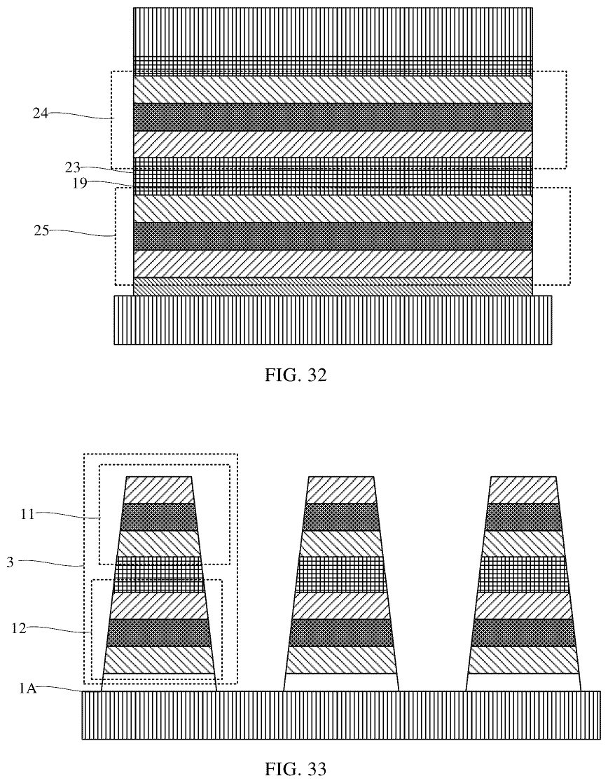

In step S3150, the second light-emitting sub-element epitaxial structure 25 and the first light-emitting sub-element epitaxial structure 24 are bonded through the first bonding sub-layer 23 and the second bonding sub-layer 19. As shown in FIG. 32, unlike the embodiment, the second light-emitting sub-element epitaxial structure is directly bonded to the first light-emitting sub-element epitaxial structure without being patterned. According to the actual process and production conditions, in some embodiments, this bonding method may improve the bonding yield.

In step S3160, the first substrate 20 is removed, and the specific content is the same as step S1670 in the method of manufacturing a display substrate according to an embodiment of the present disclosure, and will not be described in details here.

In step S3170, the second substrate 17 formed with the second light-emitting sub-element epitaxial structure and the first light-emitting sub-element epitaxial structure is bonded to the base substrate 1, and the second substrate 17 is removed, and the second light-emitting sub-element epitaxial structure and the first light-emitting sub-element epitaxial structure are patterned to form a plurality of light-emitting elements 3 on the base substrate. As shown in FIG. 33, at least one light-emitting element 3 includes a first light-emitting sub-element 11 and a second light-emitting sub-element 12, and the first light-emitting sub-element 11 and the second light-emitting sub-element 12 are stacked in a direction perpendicular to the first surface 1A of the base substrate 1. The first surface 1A is a surface of the base substrate 1 facing the light-emitting element.

It should be noted that in some embodiments, the second light-emitting sub-element epitaxial structure and the first light-emitting sub-element epitaxial structure are patterned, the formed inclination angles of the sidewalls of the first light-emitting sub-element and the second light-emitting sub-element are the same, and directions of the sidewalls of the first light-emitting sub-element and the second light-emitting sub-element are the same. The extension line of the sidewall of the first light-emitting sub-element coincides with the sidewall of the second light-emitting sub-element.

In step S3180, a second electrode 8 is formed on a side of the second light-emitting sub-element 12 away from the base substrate 1, and the specific content is the same as step S16100 in the method of manufacturing a display substrate according to an embodiment of the present disclosure, and will not be described in details here.

In step S3190, a conductive light-shielding portion 9 is formed in a gap between a plurality of light-emitting elements 3, and the light-shielding portion 9 is electrically connected to the second electrode 8, and the specific content is the same as step S16110 in the method of manufacturing a display substrate according to an embodiment of the present disclosure, and will not be described in details here.

It should be understood that a display device according to some exemplary embodiments of the present disclosure has all the features and advantages of the above-mentioned display substrate, which may be referred to the description of the display substrate above and will not be described in details here.

As used herein, the terms “substantially”, “about”, “approximately”, and other similar terms are used as terms of approximation rather than as terms of degree, and are intended to account for inherent deviations in measured or calculated values that would be recognized by those of ordinary skill in the art. Taking into account factors such as process fluctuations, measurement problems, errors associated with measurement of particular quantities (i.e., limitations of a measurement system), etc., “about” or “approximately” as used herein includes the stated values, and indicates that the particular values are within acceptable tolerances as determined by those of ordinary skill in the art. For example, “about” may mean within one or more standard deviations, or within ±10% or ±5% of the stated values.

Some embodiments according to the general inventive concept of the present disclosure have been illustrated and described. However, those of ordinary skill in the art will appreciate that changes may be made to these embodiments without departing from the principle and spirit of the general inventive concept of the present disclosure, and the scope of the present disclosure is defined by the claims and their equivalents.

1. A display substrate, comprising:
a base substrate;
a plurality of conductive patterns located on the base substrate;
a plurality of light-emitting elements located on the base substrate, wherein the plurality of light-emitting elements are arranged in an array and spaced apart from each other on the base substrate, and at least one of the light-emitting elements comprises a first electrode, a first type semiconductor layer, a light-emitting layer, a second type semiconductor layer, and a second electrode, the first electrode is electrically connected to one of the conductive patterns, the first type semiconductor layer is located on a side of the first electrode away from the base substrate, the light-emitting layer is located on a side of the first type semiconductor layer away from the base substrate, the second type semiconductor layer is located on a side of the light-emitting layer away from the base substrate, and the second electrode is located on a side of the second type semiconductor layer away from the base substrate; and
a conductive light-shielding portion located on the base substrate, wherein the light-shielding portion is located in a gap between two adjacent light-emitting elements, and is electrically connected to the second electrode.

2. The display substrate according to claim 1, wherein
the light-emitting layer comprises a top surface away from the base substrate, the light-shielding portion comprises a top surface away from the base substrate, and the base substrate comprises a first surface facing the light-emitting element; and
a height of the top surface of the light-shielding portion relative to the first surface is greater than a height of the top surface of the light-emitting layer relative to the first surface.

3. The display substrate according to claim 2, wherein the second type semiconductor layer comprises a top surface away from the base substrate, and the height of the top surface of the light-shielding portion relative to the first surface is greater than a height of the top surface of the second type semiconductor layer relative to the first surface.

4. A display substrate according to claim 2, wherein the first type semiconductor layer comprises a bottom surface close to the base substrate, the light-shielding portion comprises a bottom surface close to the base substrate, and a height of the bottom surface of the light-shielding portion relative to the first surface is less than a height of the bottom surface of the first type semiconductor layer relative to the first surface.

5. The display substrate according to claim 4, wherein the bottom surface of the light-shielding portion is in contact with the first surface.

6. The display substrate according to claim 1, wherein the first type semiconductor layer comprises a bottom surface close to the base substrate, the light-emitting element comprises a sidewall connecting the top surface of the second type semiconductor layer and the bottom surface of the first type semiconductor layer, and the sidewall of the light-emitting element is inclined relative to the bottom surface of the first type semiconductor layer.

7. The display substrate according to claim 6, wherein the light-shielding portion comprises a bottom surface close to the base substrate and a sidewall connecting the top surface of the light-shielding portion and the bottom surface of the light-shielding portion, and the sidewall of the light-shielding portion is inclined relative to the bottom surface of the light-shielding portion.

8. The display substrate according to claim 7, wherein
the sidewall of the light-emitting element is inclined at a first angle relative to the bottom surface of the first type semiconductor layer, and the first angle is less than or equal to 65°; and/or
the sidewall of the light-shielding portion is inclined at a second angle relative to the bottom surface of the light-shielding portion, and the second angle is less than or equal to 65°.

9. The display substrate according to claim 1, wherein
the display substrate further comprises: a first insulating layer located between the second type semiconductor layer and a layer where the second electrode is located; and a plurality of openings located in the first insulating layer; and
the first insulating layer comprises a first portion and a second portion, wherein the first portion of the first insulating layer covers a first part of the top surface of the second type semiconductor layer, the opening exposes another part of the top surface of the second type semiconductor layer, and the second portion of the first insulating layer covers the sidewall of the light-emitting element.

10. The display substrate according to claim 9, wherein
the second electrode comprises a first electrode portion, a second electrode portion, and a third electrode portion, wherein the first electrode portion covers the first portion of the first insulating layer, the second electrode portion covers the second portion of the first insulating layer, and the third electrode portion is located in the opening; and
the light-shielding portion is in contact with at least the first electrode portion of the second electrode.

11. The display substrate according to claim 10, wherein an orthographic projection of the light-shielding portion on the base substrate is spaced apart from an orthographic projection of the second portion of the first insulating layer on the base substrate.

12. The display substrate according to claim 11, wherein the light-shielding portion comprises a first light-shielding sub-portion and a second light-shielding sub-portion, the first light-shielding sub-portion is in contact with the first electrode portion of the second electrode, and the second light-shielding sub-portion is in contact with the second electrode portion of the second electrode.

13. The display substrate according to claim 12, wherein an orthographic projection of the second light-shielding sub-portion on the base substrate at least partially overlaps with an orthographic projection of the second electrode portion of the second electrode on the base substrate; and/or[[,]] an orthographic projection of the second light-shielding sub-portion on the base substrate at least partially overlaps with the orthographic projection of the second portion of the first insulating layer on the base substrate; and
wherein the second electrode comprises a top surface away from the base substrate, and a height of the top surface of the light-shielding portion relative to the first surface is greater than a height of the top surface of the second electrode relative to the first surface.

14. (canceled)

15. The display substrate according to claim 1, wherein
at least one of the light-emitting elements comprises a first light-emitting sub-element and a second light-emitting sub-element, the first light-emitting sub-element and the second light-emitting sub-element are stacked in a direction perpendicular to a first surface of the base substrate, and the first surface is a surface of the base substrate facing the light-emitting element;
the first light-emitting sub-element comprises a first electrode, a first type semiconductor layer, a light-emitting layer, and a second type semiconductor layer, the first electrode is electrically connected to one of the conductive patterns, the first type semiconductor layer of the first light-emitting sub-element is located on a side of the first electrode away from the base substrate, the light-emitting layer of the first light-emitting sub-element is located on a side of the first type semiconductor layer of the first light-emitting sub-element away from the base substrate, and the second type semiconductor layer of the first light-emitting sub-element is located on a side of the light-emitting layer of the first light-emitting sub-element away from the base substrate;
the second light-emitting sub-element comprises a first type semiconductor layer, a light-emitting layer, a second type semiconductor layer, and a second electrode, the first type semiconductor layer of the second light-emitting sub-element is located on a side of the second type semiconductor layer of the first light-emitting sub-element away from the base substrate, the light-emitting layer of the second light-emitting sub-element is located on a side of the first type semiconductor layer of the second light-emitting sub-element away from the base substrate, the second type semiconductor layer of the second light-emitting sub-element is located on a side of the light-emitting layer of the second light-emitting sub-element away from the base substrate, and the second electrode is located on a side of the second type semiconductor layer of the second light-emitting sub-element away from the base substrate; and
the second type semiconductor layer of the first light-emitting sub-element and the first type semiconductor layer of the second light-emitting sub-element are electrically connected through a first bonding layer;
the light-emitting layer of the second light-emitting sub-element comprises a top surface away from the base substrate, the light-shielding portion comprises the top surface away from the base substrate, and the height of the top surface of the light-shielding portion relative to the first surface is greater than a height of the top surface of the light-emitting layer of the second light-emitting sub-element relative to the first surface; and/or the light-emitting layer of the first light-emitting sub-element comprises a bottom surface close to the base substrate, the light-shielding portion comprises the bottom surface close to the base substrate, and a height of the bottom surface of the light-shielding portion relative to the first surface is less than a height of the bottom surface of the light-emitting layer of the first light-emitting sub-element relative to the first surface; and
the second type semiconductor layer of the second light-emitting sub-element comprises a top surface away from the base substrate, and the height of the top surface of the light-shielding portion relative to the first surface is greater than a height of the top surface of the second type semiconductor layer of the second light-emitting sub-element relative to the first surface; and/or the first type semiconductor layer of the first light-emitting sub-element comprises a bottom surface close to the base substrate, and the height of the bottom surface of the light-shielding portion relative to the first surface is less than a height of the bottom surface of the first type semiconductor layer of the first light-emitting sub-element relative to the first surface.

16-17. (canceled)

18. The display substrate according to claim 15, wherein the bottom surface of the light-shielding portion is in contact with the first surface;
wherein the light-emitting element comprises a sidewall connecting the top surface of the second type semiconductor layer of the second light-emitting sub-element and the bottom surface of the first type semiconductor layer of the first light-emitting sub-element, and the sidewall of the light-emitting element is inclined relative to the bottom surface of the first type semiconductor layer of the first light-emitting sub-element;
wherein the light-shielding portion comprises the bottom surface close to the base substrate and a sidewall connecting the top surface of the light-shielding portion and the bottom surface of the light-shielding portion, and the sidewall of the light-shielding portion is inclined relative to the bottom surface of the light-shielding portion;
wherein the sidewall of the light-emitting element is inclined at a first angle relative to the bottom surface of the first type semiconductor layer, and the first angle is less than or equal to 65°; and/or, the sidewall of the light-shielding portion is inclined at a second angle relative to the bottom surface of the light-shielding portion, and the second angle is less than or equal to 65°; and
wherein the first bonding layer comprises a bottom surface facing the second type semiconductor layer of the first light-emitting sub-element, a top surface facing the first type semiconductor layer of the second light-emitting sub-element, and a sidewall connecting the bottom surface of the first bonding layer and the top surface of the first bonding layer; and the sidewall of the first bonding layer is inwardly recessed relative to the sidewall of the second type semiconductor layer of the adjacent first light-emitting sub-element, and/or the sidewall of the first bonding layer is inwardly recessed relative to the sidewall of the first type semiconductor layer of the adjacent second light-emitting sub-element.

19-22. (canceled)

23. The display substrate according to claim 1, wherein the display substrate further comprises a lens located on the base substrate, the lens is located on a side of the second electrode away from the base substrate, and an orthographic projection of the lens on the base substrate covers an orthographic projection of the opening on the base substrate;
wherein the orthographic projection of the lens on the base substrate at least partially overlaps with an orthographic projection of the second portion of the first insulating layer on the base substrate; and/or, the orthographic projection of the lens on the base substrate at least partially overlaps with an orthographic projection of the second portion of the second electrode on the base substrate; and
wherein the orthographic projection of the lens on the base substrate at least partially overlaps with an orthographic projection of the light-shielding portion on the base substrate.

24-25. (canceled)

26. A display panel, comprising:
the display substrate according to claim 1;
a cover plate arranged opposite to the display substrate; and
an adhesive layer located between the display substrate and the cover plate.

27. A method of manufacturing the display substrate according to claim 1, comprising:
forming a plurality of conductive patterns on a base substrate;
bonding a light-emitting element epitaxial wafer to the base substrate formed with the plurality of conductive patterns;
patterning the light-emitting element epitaxial wafer to form a plurality of light-emitting elements arranged in an array and spaced apart from each other on the base substrate, wherein at least one of the light-emitting elements comprises a first electrode, a first type semiconductor layer, a light-emitting layer, and a second type semiconductor layer, wherein the first electrode is electrically connected to one of the conductive patterns, the first type semiconductor layer is located on a side of the first electrode away from the base substrate, the light-emitting layer is located on a side of the first type semiconductor layer away from the base substrate, and the second type semiconductor layer is located on a side of the light-emitting layer away from the base substrate; and
forming a second electrode on a side of the second type semiconductor layer away from the base substrate; and
forming a conductive light-shielding portion in a gap between the plurality of light-emitting elements, wherein the light-shielding portion is electrically connected to the second electrode.

28. A method of manufacturing a display substrate, comprising:
forming a second light-emitting sub-element epitaxial structure on a second substrate;
forming a second bonding sub-layer on a side of the second light-emitting sub-element epitaxial structure away from the second substrate;
patterning the second light-emitting sub-element epitaxial structure and the second bonding sub-layer to form a second light-emitting sub-element, wherein the second light-emitting sub-element comprises a second type semiconductor layer, a light-emitting layer, and a first type semiconductor layer, the second type semiconductor layer of the second light-emitting sub-element is located on the second substrate, the light-emitting layer of the second light-emitting sub-element is located on a side of the second type semiconductor layer of the second light-emitting sub-element away from the first substrate, and the first type semiconductor layer of the second light-emitting sub-element is located on a side of the light-emitting layer of the second light-emitting sub-element away from the first substrate;
forming a first light-emitting sub-element epitaxial structure on a first substrate;
forming a first bonding sub-layer on a side of the first light-emitting sub-element epitaxial structure away from the first substrate;
bonding the second light-emitting sub-element and the first light-emitting sub-element epitaxial structure through the first bonding sub-layer and the second bonding sub-layer;
removing the first substrate;
patterning the first light-emitting sub-element epitaxial structure and the first bonding sub-layer to form a first light-emitting sub-element, wherein the first light-emitting sub-element comprises a second type semiconductor layer, a light-emitting layer, and a first type semiconductor layer, the second type semiconductor layer of the first light-emitting sub-element is located on the first bonding sub-layer, the light-emitting layer of the first light-emitting sub-element is located on a side of the second type semiconductor layer of the first light-emitting sub-element away from the second substrate, and the first type semiconductor layer of the first light-emitting sub-element is located on a side of the light-emitting layer of the first light-emitting sub-element away from the second substrate; and
bonding the second substrate formed with the first light-emitting sub-element and the second light-emitting sub-element to a base substrate, and removing the second substrate to form a plurality of light-emitting elements on the base substrate, wherein at least one of the light-emitting elements comprises a first light-emitting sub-element and a second light-emitting sub-element, the first light-emitting sub-element and the second light-emitting sub-element are stacked in a direction perpendicular to a first surface of the base substrate, wherein the first surface is a surface of the base substrate facing the light-emitting element;
forming a second electrode on a side of the second type semiconductor layer of the second light-emitting sub-element away from the base substrate; and
forming a conductive light-shielding portion in a gap between the plurality of light-emitting elements, wherein the light-shielding portion is electrically connected to the second electrode.

29. A method of manufacturing a display substrate, comprising:
forming a second light-emitting sub-element epitaxial structure on a second substrate;
forming a second bonding sub-layer on a side of the second light-emitting sub-element epitaxial structure away from the second substrate;
forming a first light-emitting sub-element epitaxial structure on a first substrate;
forming a first bonding sub-layer on a side of the first light-emitting sub-element epitaxial structure away from the first substrate;
bonding the second light-emitting sub-element epitaxial structure and the first light-emitting sub-element epitaxial structure through the first bonding sub-layer and the second bonding sub-layer;
removing the first substrate;
bonding the second substrate formed with the second light-emitting sub-element epitaxial structure and the first light-emitting sub-element epitaxial structure to a base substrate, removing the second substrate, and patterning the second light-emitting sub-element epitaxial structure and the first light-emitting sub-element epitaxial structure to form a plurality of light-emitting elements on the base substrate, wherein at least one of the light-emitting elements comprises a first light-emitting sub-element and a second light-emitting sub-element, the first light-emitting sub-element and the second light-emitting sub-element are stacked in a direction perpendicular to a first surface of the base substrate, and the first surface is a surface of the base substrate facing the light-emitting element;
forming a second electrode on a side of the second light-emitting sub-element away from the base substrate; and
forming a conductive light-shielding portion in a gap between the plurality of light-emitting elements, wherein the light-shielding portion is electrically connected to the second electrode.
